(19) United States
(12) Patent Application Publication
(10) Pub. No.: US 2007/0158830 A1
(43) Pub. Date: Jul. 12, 2007

(54) Circuit module

(76) Inventors: Yoshiaki Miyamoto, Atsugi-Shi (JP); Osamu Tajima, Atsugi-Shi (JP)

Correspondence Address: LADAS & PARRY LLP, 224 SOUTH MICHIGAN AVENUE, SUITE 1600, CHICAGO, IL, 60604, US

(21) Appl. No.: 11/511,733

(22) Filed: Aug. 29, 2006

(30) Foreign Application Priority Data
Nov. 30, 2005 (JP) 2005-346825

(51) Int. Cl. H01L 23/34

(52) U.S. Cl. 257/724; 257/E23.18

(57) ABSTRACT

A circuit module is disclosed that includes a bare chip and a surface mounting component mounted on a surface of a substrate, and a sealing resin for sealing the bare chip and the surface mounting component. The sealing resin is molded entirely on the surface of the substrate by transfer molding.

### BACKGROUND OF THE INVENTION

1. Field of the Invention

The present invention generally relates to circuit module, and more particularly to a circuit module having a bare chip and a surface mounting component mounted on a substrate and sealed with a sealing resin.

2. Description of the Related Art

A battery protection module is one example of a circuit module having a bare chip and a surface mounting component mounted on a substrate and hermetically sealed with a sealing resin. A rechargeable battery pack used for, for example, a mobile phone includes a lithium-ion battery installed in an insulating package. Such battery pack includes a battery protection module for preventing overdischarge or overcharge with respect to the lithium-ion battery.

FIGS. 5-7 are schematic drawings for describing an example of a conventional circuit module 100. In the description below, a battery protection module is described as an example of the circuit module 100. FIG. 5 is a front view of a circuit module 100. FIG. 6 is a plan view showing a state where a sealing resin 115 is removed from the circuit module 100. FIG. 7 shows the circuit module 100 assembled to a battery pack 120.

The circuit module 100 is a COB (Chip On Board) type module. As shown in FIG. 6, the circuit module 100 is configured having a bare chip 112 and a surface mounting component(s) 113 mounted on a circuit substrate 111. A wire(s) 114 is provided between the bare chip 112 and a bonding pad (not shown) formed on the surface of the circuit substrate 111. Furthermore, the surface mounting component(s) 113 is soldered on the surface of an electrode formed on the surface circuit substrate 111.

The bare chip 112, the surface mounting component 113, and the wire 114 mounted on the circuit substrate 111 face problems such as anti-corrosion and mechanical strength when in an exposed state. Therefore, the bare chip 112, the surface mounting component 113, and the wire 114 are, in general, sealed with a sealing resin 115 for obtaining sufficient reliability.

As a conventional method of forming the sealing resin 115 on the circuit substrate 111, there is a method of drooping liquid resin onto the circuit substrate 111 by potting and then heating and curing the resin (For example, Japanese Laid-Open Patent Application No. 2002-190564).

In the method of forming the sealing resin 115 by the potting, the liquid resin is dropped onto the circuit substrate 111 by using a dispenser. Accordingly, the dropped liquid resin spreads on the surface of the circuit substrate 111 in accordance with properties of the liquid resin (e.g. viscosity). Thereby, the bare chip 112, the surface mounting component 113, and the wire 114 become a state of being buried inside the liquid resin. In this state, the sealing resin 115 is thermally cured.

With the method using potting, it is difficult to uniformly control the spread state of the liquid resin on the circuit substrate 111. This causes the height of the sealing resin 115 (see arrow H2 in FIG. 5) to vary. Accordingly, as shown in FIG. 7, in a case where the circuit module 100 is assembled to the battery pack 120, the sealing resin 115 and the main body of the battery (battery main body) 122 cannot be closely disposed to each other. Therefore, it becomes necessary to provide a clearance (see arrow ΔH in FIG. 7) having the height error of the sealing resin 115. Therefore, in a case where a potting method is used for forming the sealing resin 115 on the circuit module 100, the battery pack 120 has an undesired tendency of becoming large particularly in the direction indicated with arrow Z of FIG. 7.

Furthermore, in a case where the potting method is used, the circuit substrate 111 is set with a larger area than the area where the sealing resin 115 is formed in order to prevent the liquid resin from spreading beyond the outer periphery of the circuit substrate 111. Therefore, as shown in FIG. 5, when the forming of the sealing resin 115 is completed, there remains an area(s) where no sealing resin 115 is formed at the outer periphery of the circuit substrate 111 (indicated with A in FIG. 5). This area A becomes the so-called dead space and leads to increase of size of the circuit module 100. Accordingly, the size of the battery case 121 containing the battery main body 122 becomes large when the circuit module 100 is assembled to the battery pack 120. Hence, the size of the battery pack 120 becomes large particularly in the direction shown with arrow X of FIG. 5.

### SUMMARY OF THE INVENTION

It is a general object of the present invention to provide a circuit module that substantially obviates one or more of the problems caused by the limitations and disadvantages of the related art.

Features and advantages of the present invention will be set forth in the description which follows, and in part will become apparent from the description and the accompanying drawings, or may be learned by practice of the invention according to the teachings provided in the description. Objects as well as other features and advantages of the present invention will be realized and attained by circuit module particularly pointed out in the specification in such full, clear, concise, and exact terms as to enable a person having ordinary skill in the art to practice the invention.

To achieve these and other advantages and in accordance with the purpose of the invention, as embodied and broadly described herein, the invention provides a circuit module including: a bare chip and a surface mounting component mounted on a surface of a substrate; and a sealing resin for sealing the bare chip and the surface mounting component; wherein the sealing resin is molded entirely on the surface of the substrate by transfer molding.

In the circuit module according to an embodiment of the present invention, the bare chip may be connected to the substrate with a wire, wherein the wire is oriented in a longitudinal direction of the substrate.

In the circuit module according to an embodiment of the present invention, the surface mounting component may have a rectangular shape, wherein the longitudinal side of the surface mounting component is oriented in the longitudinal direction of the substrate.

In the circuit module according to an embodiment of the present invention, the sealing resin may include a first surface and a second surface situated closer to the substrate than the first surface, wherein the first surface includes a flat surface that is substantially parallel to the substrate.

Other objects and further features of the present invention will be apparent from the following detailed description when read in conjunction with the accompanying drawings.

### BRIEF DESCRIPTION OF THE DRAWINGS

FIG. 1A is a cross-sectional view showing a circuit module according to an embodiment of the present invention;

FIG. 1B is a front view showing a circuit module according to an embodiment of the present invention;

FIG. 2 is a schematic drawing showing a state where a circuit module is mounted to a battery pack according to an embodiment of the present invention;

FIG. 3 is a plan view showing a state where a sealing resin of a circuit module is removed according to an embodiment of the present invention;

FIG. 4 is a schematic diagram for describing a method of manufacturing a circuit module according to an embodiment of the present invention;

FIG. 5 is a front view of a conventional circuit module;

FIG. 6 is a plan view of a conventional circuit module showing a state where a sealing resin of the conventional circuit module is removed; and

FIG. 7 is a schematic view showing a state where the conventional circuit module is assembled to a battery pack.

### DESCRIPTION OF THE PREFERRED EMBODIMENTS

In the following, embodiments of the present invention will be described with reference to the accompanying drawings.

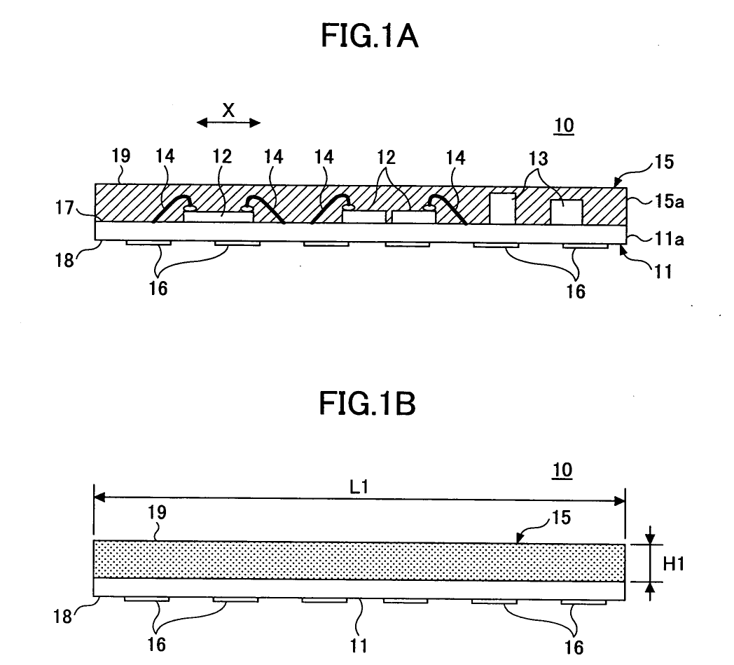

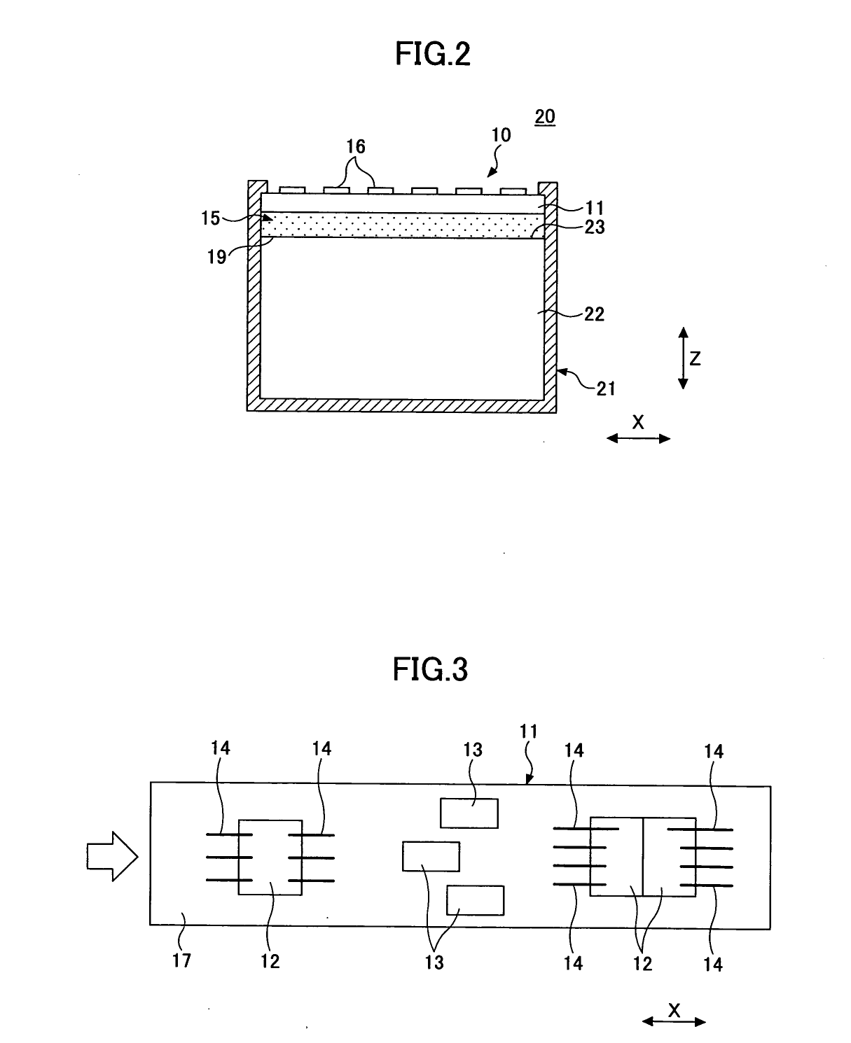

FIGS. 1A, 1B and 2 are schematic drawings for describing a circuit module 10 according to an embodiment of the present invention. It is to be noted that, in the following description, a battery protection module is used as an example of the circuit module 10.

FIG. 1A is a cross-sectional view of the circuit module 10. FIG. 1B is a front view of the circuit module 10. FIG. 2 is a schematic diagram showing the circuit module 10 assembled to a battery pack 20. The circuit module 10 according to an embodiment of the present invention is a COB (Chip On Board) type module. The circuit module 10 includes, for example, a bare chip 12 and a surface mounting component 13 mounted on a substrate 11 and a sealing resin 15 sealing the bare chip 12 and the surface mounting component 13.

The circuit substrate 11 is, for example, a multi-layer resin substrate. The circuit substrate 11 has, for example, a bonding pad (not shown) and/or an electrode (not shown) formed on its top surface 17. The circuit substrate 11 has a terminal electrode 16 formed on its bottom surface 18. In this example, the bonding pad and/or electrode formed on the top surface 17 are connected to the terminal electrode 16 formed on the bottom surface 18 via inner wiring formed inside the circuit substrate 11.

The bare chip 12 is, for example, an IC or a FET. The bare chip 12 is fixed to the circuit substrate 11 in a manner facing upward. The bare chip can be fixed on the circuit substrate 11 by using, for example, an adhesive agent. An electric connection between the bare chip 12 and the circuit substrate 11 is achieved by using a wiring 14. That is, a wire bonding process is performed between an electrode pad formed on an upper part of the bare chip 12 and a bonding pad formed on the top surface 17 of the circuit substrate 11. Thereby, the circuit substrate 11 and the bare chip 12 are electrically connected by the wiring 14.

The surface mounting component 13 includes, for example, a condenser and/or a resistance. The surface mounting component 13 is soldered on the surface of an electrode (not shown) formed on the top surface 17 of the circuit substrate 11. In FIG. 1A, although the height of the surface mounting component 13 with respect to the top surface 17 is greater than the height of the loop of the wiring 14, the height of the loop of the wiring 14 may be greater than that of the surface mounting component 13 depending on the type of the surface mounting component. The height of the sealing resin 15 (indicated with arrow H1 in FIG. 1B) is set with reference to the component that is highest with respect to the top surface 17 (described in detail below).

The terminal electrode 16 is an electrode for connecting the circuit module 10 to the external (external connection). In a case where the circuit module 10 is mounted to a battery pack 20, the terminal electrode 16 is in an exposed state at the outer part of the battery pack 20 as shown in FIG. 2. Thereby, the circuit module 10 can connect to an external circuit (e.g. communication circuit of a mobile phone).

Next, the sealing resin 15 is described in further detail.

As described above, it is difficult to attain reliability where the circuit substrate 11 has, for example, the bare chip 12, the surface mounting component 13, and the wiring 14 mounted on its surface in an exposed state. Therefore, the bare chip 12, the surface mounting component 13, and the wiring 14 are generally sealed by the sealing resin 15. The sealing resin 15 according to an embodiment of the present invention is molded by using a transfer molding method. Furthermore, the sealing resin 15 according to an embodiment of the present invention is formed on entirely on the top surface 17. Thereby, the bare chip 12, the surface mounting component 13, and the wiring 14 can be sealed by the sealing resin 15. The material of the sealing resin includes a thermosetting resin such as epoxy.

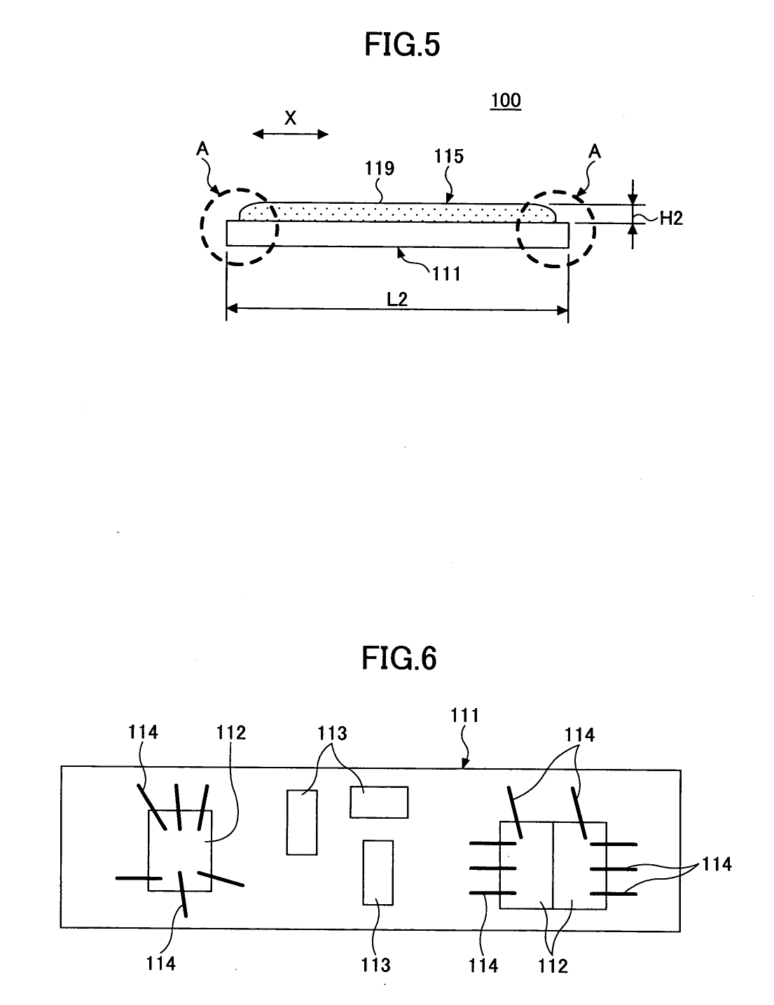

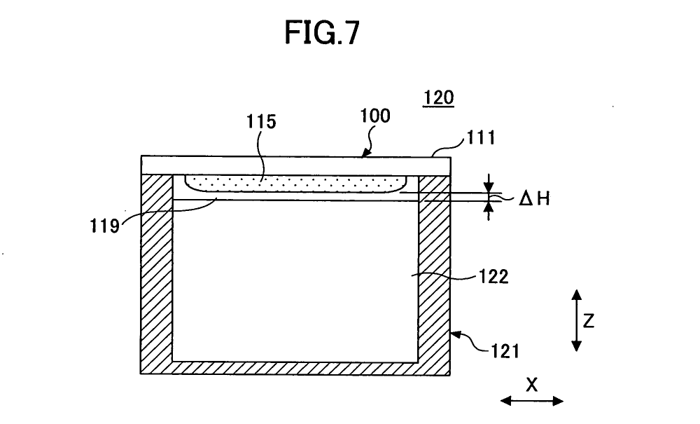

Since the sealing resin 15 according to an embodiment of the present invention seals the bare chip 12 and the surface mounting component 13 on the circuit substrate 11 by using transfer molding method, the sealing resin 15 can be molded with a more precise height compared to the method of forming the sealing resin 115 by using the potting method (see FIG. 5). That is, the conventional method of forming the sealing resin 115 by using the potting method causes the height of the sealing resin 115 (see H2 of FIG. 5) to vary considerably. Meanwhile, in the method of forming the sealing resin 15 by using the transfer molding method, the sealing resin 15 can be formed with a precise height H1 (see H1 of FIG. 1B) since the sealing resin 15 is formed by using a die (not shown).

As described above, in a case where the potting method is used, the circuit substrate 111 is set with a larger area than the area where the sealing resin 115 is formed so as to prevent the liquid resin from spreading beyond the outer periphery of the circuit substrate 111 (see area indicated with arrow A in FIG. 5). However, in a case where the transfer molding method is used for forming the sealing resin 15, no space for preventing liquid resin from spreading beyond the outer periphery of the circuit substrate 11.

Accordingly, the so-called dead space can be prevented from being created when forming the sealing resin 15. Thereby, the circuit module 10 can be formed smaller. More specifically, the length of the sealing resin 15 can be shorted in the direction indicated with arrow X (longitudinal direction). Accordingly, the length of the circuit module 10 in the longitudinal direction (length L1 shown in FIG. 1B) can be shortened. Furthermore, since the side surface 15a of the sealing resin 15 matches with the side surface 11a of the circuit substrate 11, unnecessary space can be prevented from being formed in the battery pack 20 in a case of mounting the circuit module 10 to the battery pack 20 as shown in FIG. 2.

Furthermore, when executing the transfer molding method, a resin top surface 19 (surface situated opposite of the surface of the sealing resin 15 facing the circuit substrate) is formed as a plane being substantially parallel to the circuit substrate 11. Thereby, the resin top surface 19 can directly contact the end surface 23 of the battery main body 22 when mounting the circuit module 10 to the battery pack 20.

Accordingly, in case where the circuit module 10 is mounted to the battery pack 20, the creation of dead space in a battery case 21 can be prevented, and the battery pack 20 can be formed in a smaller size particular toward the direction indicated with arrow Z of FIG. 2. Hence, by applying the circuit module 10 to the battery pack 20, the size of the battery pack 20 can be reduced in the directions indicated by arrows X and Z of FIG. 2.

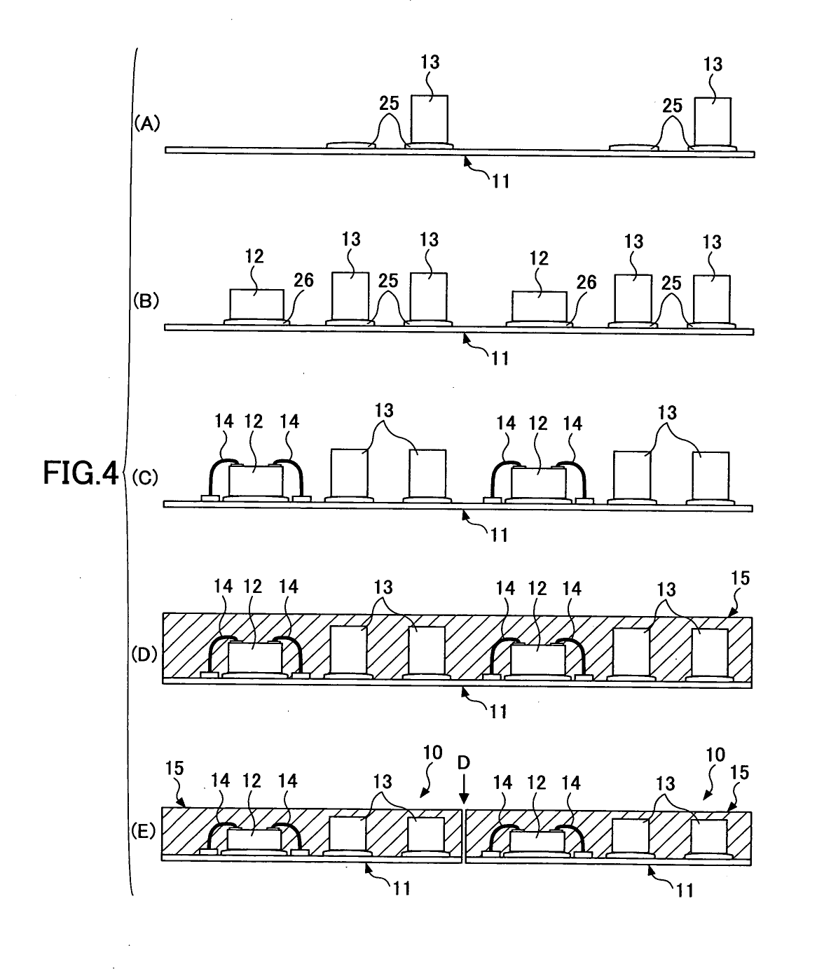

Next, a method of manufacturing the circuit module 10 according to an embodiment of the present invention is described. FIG. 4 is a schematic drawing for describing the method of manufacturing the circuit module 10 according to an embodiment of the present invention.

In manufacturing the circuit module 10, first, solder paste 25 is coated on an electrode formed on the circuit substrate 11 (substrate not in a divided state). The method of coating the solder paste 25 includes, for example, a screen printing method. The surface mounting component 13 is mounted on the coated solder paste 25 as shown in (A) of FIG. 4. Then, the bare chip 12 is adhered to a predetermined position by using an adhesive agent 26. After the surface mounting component 13 is temporarily fixed on the electrode via the solder paste 25, the circuit substrate 11 is heated (thermally processed) by being placed into a reflow oven. Accordingly, the solder in the solder paste 25 melts, to thereby solder the surface mounting component 13 to the circuit substrate 11.

Then, the bare chip 12 is temporarily fixed to the circuit substrate 11 by using an adhesive agent 26. By thermally curing the circuit substrate 11 with an oven, the bare chip 12 is adhered to the circuit substrate 11. (B) in FIG. 4 shows a state where the bare chip 12 and the surface mounting component 13 are mounted on the circuit substrate 11.

Then, the wire 14 is employed for wire bonding the electrode pad (not shown) formed on the upper part of the bare chip 12 and the bonding pad (not shown) formed on the top surface 17 of the circuit substrate 11. Accordingly, as shown in (C) of FIG. 4, the circuit substrate 11 and the bare chip 12 are electrically connected by the wiring 14.

Then, the circuit substrate 11 having the bare chip 12 and the surface mounting component 13 mounted thereon is placed inside a die (not shown) for conducting transfer molding. In conducting the transfer molding method, it is preferable to have the wiring 14 extended in the longitudinal direction of the circuit substrate 11 (indicated by arrow X in FIG. 3) and also to inject resin (which is to become sealing resin 15) in the die also in the in the longitudinal direction of the circuit substrate 11 (indicated by arrow X in FIG. 3). Thereby, the wiring 14 can be prevented from changing position when conducting the transfer molding so that neighboring wires 14 can be prevented from interfering with each other.

Furthermore, in mounting the surface mounting component 13 on the circuit substrate 11, it is also preferable to have a longitudinal side of a rectangular surface mounting component 13 disposed in parallel to the longitudinal direction of the circuit substrate 11 (as shown by the large arrow of FIG. 3) and also to inject resin (which is to become sealing resin 15) in the die also in the in the longitudinal direction of the circuit substrate 11 (indicated by arrow X in FIG. 3). Thereby, the resin injected in the die can flow smoothly so that voids can be prevented from being created inside the sealing resin 15.

After the sealing resin 15 is formed by conducting the foregoing procedures, the circuit substrate 11 is diced into predetermined pieces by dicing the circuit substrate 11 diced at a predetermined part indicated with arrow D in (E) of FIG. 4. Thereby, the manufacturing of the circuit module 10 is completed.

Further, the present invention is not limited to these embodiments, but variations and modifications may be made without departing from the scope of the present invention.

The present application is based on Japanese Priority Application No. 2005-346825 filed on Nov. 30, 2005, with the Japanese Patent Office, the entire contents of which are hereby incorporated by reference.

What is claimed is:

1. A circuit module comprising:
a bare chip and a surface mounting component mounted on a surface of a substrate; and
a sealing resin for sealing the bare chip and the surface mounting component;
wherein the sealing resin is molded entirely on the surface of the substrate by transfer molding.

2. The circuit module as claimed in claim 1, wherein the bare chip is connected to the substrate with a wire, wherein the wire is oriented in a longitudinal direction of the substrate.

3. The circuit module as claimed in claim 1, wherein the surface mounting component has a rectangular shape, wherein the longitudinal side of the surface mounting component is oriented in the longitudinal direction of the substrate.

4. The circuit module as claimed in claim 1, wherein the sealing resin includes a first surface and a second surface situated closer to the substrate than the first surface, wherein the first surface includes a flat surface that is substantially parallel to the substrate.
